(19) United States
(12) Patent Application Publication
(10) Pub. No.: US 2020/0335456 A1
(43) Pub. Date: Oct. 22, 2020

(54) SEMICONDUCTOR PACKAGE AND MANUFACTURING METHOD THEREOF

(71) Applicant: Powertech Technology Inc., Hsinchu County (TW)

(72) Inventor: Wen-Jeng Fan, Hsinchu County (TW)

(73) Assignee: Powertech Technology Inc., Hsinchu County (TW)

(21) Appl. No.: 16/384,940

(22) Filed: Apr. 16, 2019

(51) Int. Cl. H01L 23/00; H01L 23/31; H01L 23/538; H01L 25/10; H01L 21/48; H01L 21/56; H01L 25/00

(52) U.S. Cl. CPC H01L 23/562; H01L 2225/1035; H01L 23/5383; H01L 23/5386; H01L 23/5389; H01L 24/20; H01L 25/105; H01L 21/4857; H01L 21/4853; H01L 21/568; H01L 21/565; H01L 24/19; H01L 25/50; H01L 2224/214; H01L 2924/351; H01L 2225/1058; H01L 23/3128

(57) ABSTRACT

A semiconductor package including a semiconductor chip, a conductive element disposed adjacent to the semiconductor chip, an insulating encapsulation covering the semiconductor chip and the conductive element, a redistribution structure disposed on the semiconductor chip and the conductive element, and a first buffer layer disposed between the redistribution structure and the insulating encapsulation is provided. The semiconductor chip is electrically coupled to the conductive element through the redistribution structure. The first buffer layer covers the semiconductor chip and the conductive element. A manufacturing method of a semiconductor package is also provided.

### BACKGROUND OF THE INVENTION

### 1. Field of the Invention

The present invention generally relates to a package structure and a manufacturing method thereof, and more particularly, to a semiconductor package and a manufacturing method thereof.

### 2. Description of Related Art

In recently years, electronic apparatus are more important for human's life. In order for electronic apparatus design to achieve being light, slim, short, and small, semiconductor packaging technology has kept progressing, in attempt to develop products that are smaller in volume, lighter in weight, higher in integration, and more competitive in market. Since the chip package technique is highly influenced by the development of integrated circuits, therefore, as the size of electronics has become demanding, so does the package technique. As such, miniaturizing the semiconductor package and keeping the reliability of the semiconductor package while maintaining the process simplicity has become a challenge to researchers in the field.

### SUMMARY OF THE INVENTION

The disclosure provides a semiconductor package and a manufacturing method thereof, which improves the reliability of the semiconductor package and the processing yield.

The disclosure provides a semiconductor package including a semiconductor chip, a conductive element disposed adjacent to the semiconductor chip, an insulating encapsulation encapsulating a portion of the semiconductor chip and the conductive element, a redistribution structure disposed on the semiconductor chip and the conductive element, and a first buffer layer disposed between the redistribution structure and the insulating encapsulation. The semiconductor chip and the conductive element are electrically coupled to the redistribution structure. The first buffer layer encapsulates another portion of the semiconductor chip and the conductive element.

The disclosure provides a manufacturing method of a semiconductor package. The method includes at least the following steps. An insulating encapsulation is formed to partially cover a semiconductor chip and a conductive element, where a portion of the conductive element and a portion of the semiconductor chip are exposed by the insulating encapsulation. A first buffer layer is formed on the insulating encapsulation to partially cover the portion of the conductive element and the portion of the semiconductor chip. A redistribution structure is formed on the first buffer layer, wherein the redistribution structure is electrically connected to the semiconductor chip and the conductive element.

Based on the above, the semiconductor package includes the first buffer layer formed between the insulating encapsulation and the redistribution structure, so that the first buffer layer can be used to buffer the stress generated from a subsequently formed the redistribution structure. Accordingly, the reliability and quality of the semiconductor package are improved. In addition, the total thickness of the first buffer layer and the insulating encapsulation is substantially equal to the height of the conductive element or the height of the semiconductor chip, so that the entire thickness of the semiconductor package is not compromised. Moreover, the buffer layers may be formed at two opposite sides of the insulating encapsulation to form a sandwich-type of encapsulation structure for stress buffering. Furthermore, multiple semiconductor packages may be stacked upon one another to provide additional functionality to form a POP structure so as to open the possibility to various package designs.

To make the above features and advantages of the present invention more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1H are schematic cross-sectional views illustrating a manufacturing method of a semiconductor package according to an embodiment of the disclosure.

FIG. 2 is an enlarged schematic cross-sectional view illustrating a dashed box A depicted in FIG. 1F according to an embodiment of the disclosure.

FIG. 3A to FIG. 3C are schematic cross-sectional views illustrating a manufacturing method of a semiconductor package according to an embodiment of the disclosure.

FIG. 4 is a schematic cross-sectional view illustrating an application of semiconductor package according to an embodiment of the disclosure.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

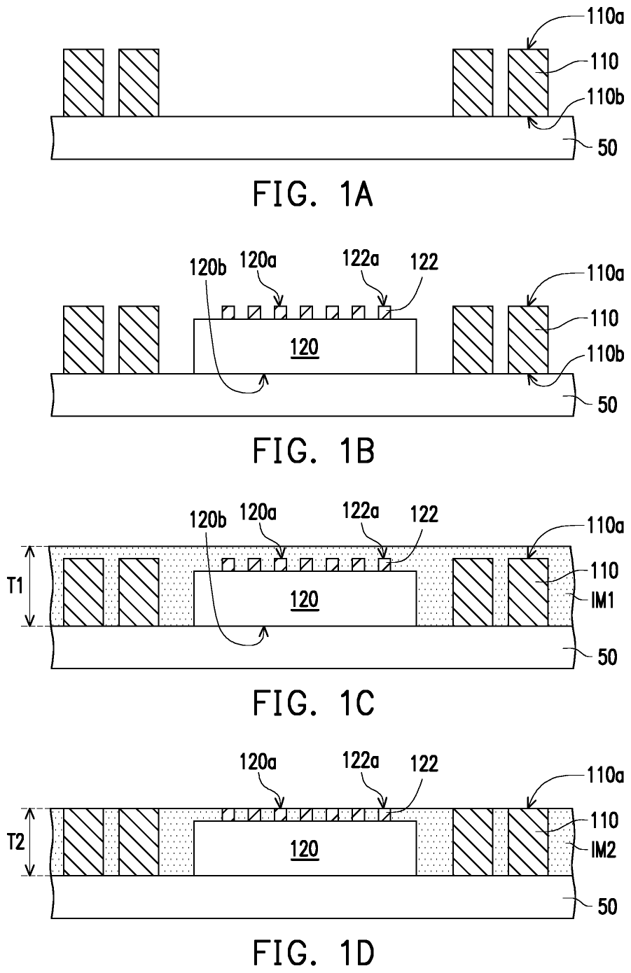

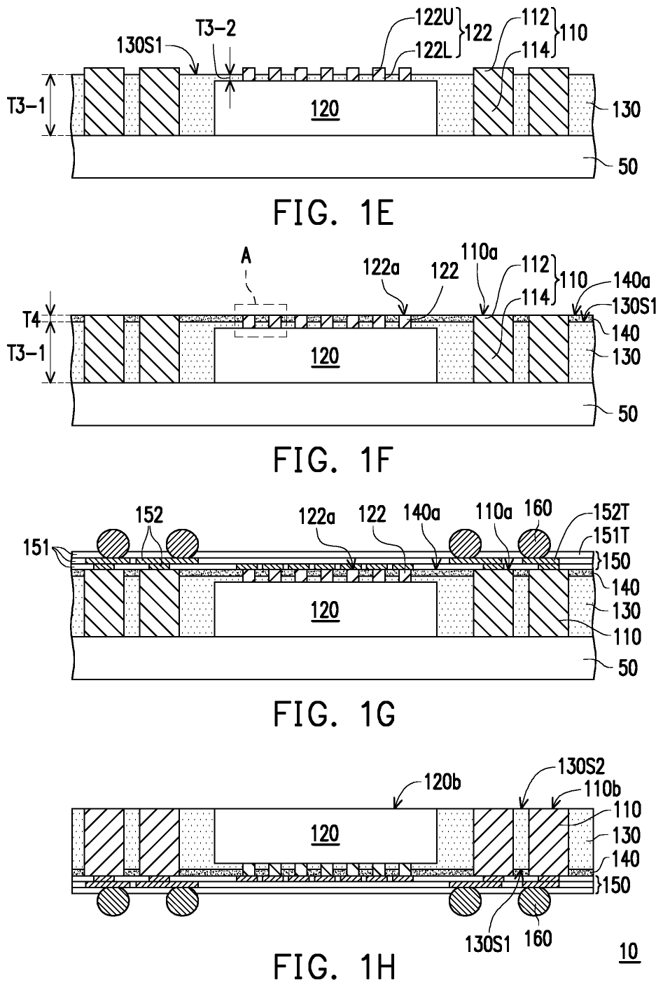

FIG. 1A to FIG. 1H are schematic cross-sectional views illustrating a manufacturing method of a semiconductor package according to an embodiment of the disclosure, and FIG. 2 is an enlarged schematic cross-sectional view illustrating a dashed box A depicted in FIG. 1F according to an embodiment of the disclosure. Referring to FIG. 1A, a conductive element 110 is disposed on a temporary carrier 50. The temporary carrier 50 may be made of glass, plastic or other suitable materials as long as the material is able to withstand the subsequent processes while carrying the structure formed thereon. In some embodiments, a de-bonding layer (not shown) is provided between the conductive element 110 and the temporary carrier 50 to enhance the releasibility of the conductive element 110 from the temporary carrier 50 in the subsequent processes. The de-bonding layer may be a light to heat conversion (LTHC) adhesive layer, or other suitable adhesive layers.

The conductive element 110 includes a first surface 110a and a second surface 110b opposite to the first surface 110a. The second surface 110b of the conductive element 110 may be facing toward the temporary carrier 50. A material of the conductive element 110 includes copper, nickel, gold, tin, lead, a combination thereof, or other suitable conductive materials. The conductive element 110 may have the shape of pillars. The top view shape of the conductive element 110 may be circles, rectangles, squares, polygons, or the like. In some embodiments, a plurality of the conductive elements 110 is distributed on the temporary carrier 50. The conductive elements 110 may be formed through a plating process (e.g., electro-plating, electroless-plating, immersion plating), or other suitable deposition processes. In alternative embodiments, the conductive elements 110 may be pre-formed and disposed on the temporary carrier 50 through a pick and place process. The height of the conductive elements 110 may be determined by the thickness of the subsequently placed semiconductor chip.

Referring to FIG. 1B, a semiconductor chip 120 is disposed on the temporary carrier 50 adjacent to the conductive element 110 by a pick and place process, or other suitable techniques. The semiconductor chip 120 is surrounded by the conductive elements 110. It should be appreciated that the number of the chips in FIG. 1B merely serves as an exemplary illustration and the disclosure is not limited thereto. The semiconductor chips 120 may include a memory chip, a logic chip, a calculating chip, an ASIC (Application-Specific Integrated Circuit), or other suitable active devices. It should be noted that the foregoing sequence merely serves as an illustrative example. In some embodiments, the semiconductor chip 120 is disposed on the temporary carrier 50 before forming/disposing the conductive elements 110.

Each semiconductor chip 120 has a first side 120a and a second side 120b opposite the first side 120a. The second side 120b may be facing toward the temporary carrier 50. The first side 120a of the semiconductor chip 120 may include a plurality of conductive bumps 122. Each of the conductive bumps 122 has a first surface 122a. A material of the conductive bumps 122 may be copper, tin, gold, nickel, solder, a combination thereof, or the like. In some embodiments, the semiconductor chip 120 is manufactured by the following steps. A wafer (not illustrated) having active components (e.g., transistors or the like) and, optionally, passive components (e.g., resistor, capacitor, inductor, or the like) formed therein is provided. An interconnection structure is formed over the wafer. The interconnection structure may include at least one circuit layer and at least one dielectric layer alternatingly formed. The dielectric layer of the interconnection structure may be made of a semiconductor oxide material including silicon oxide, silicon oxynitride, a combination thereof, or other suitable material. The conductive bumps 122 are formed over and are electrically connected the interconnection structure. The wafer is diced to obtain a plurality of the semiconductor chips 120.

Referring to FIG. 1C, an insulating material IM1 is formed over the temporary carrier 50 to bury the conductive elements 110 and the semiconductor chip 120. The insulating material IM1 may be polymer, epoxy resin, molding compound, or other suitable electrically insulating materials. The insulating material IM1 may be a molding compound formed by molding processes. After forming the insulating material IM1, the first surfaces 122a of the conductive bumps 122 and the first surfaces 110a of the conductive elements 110 are covered by the insulating material IM1. A first thickness T1 of the insulating material IM1 may be greater than the height of the conductive element 110 and the height (e.g., measured from the first side 120a to the second side 120b) of the semiconductor chip 120 corresponding to the temporary carrier 50.

Referring to FIG. 1D and FIG. 1E, after forming the insulating material IM1, a thinning process is performed to form an insulating encapsulation 130. In some embodiments, a thinning process includes two steps. First, the first thickness T1 of the insulating material IM1 may be reduced to form a thinned insulating material IM2 having the second thickness T2 as shown in FIG. 1D. The first step of thinning process may be performed on the insulating material IM1 until the first surfaces 122a of the conductive bumps 122 and/or the first surfaces 110a of the conductive elements 110 are exposed as shown in FIG. 1D. The first step of thinning process may be a mechanical grinding process and/or a chemical mechanical polishing (CMP) process, a laser ablation process, or any other suitable process. The first step of thinning process, may further remove portions of the conductive bumps 122 at the first side 120a of the semiconductor chip 120 and/or portions of the conductive elements 110. The first step of thinning process may form a substantially planar surface of the thinned insulating material IM2.

Next, a part of the thinned insulating material IM2 is removed to form the insulating encapsulation 130 as shown in FIG. 1E. A thickness of the thinned insulating material IM2 is reduced to expose first portions 112 of the conductive elements 110 and upper portions 122U of the conductive bumps 122 of the semiconductor chip 120. The first portions 112 of the conductive elements 110 and the upper portions 122U of the conductive bumps 122 may be protruding from a first surface 130S1 of the insulating encapsulation 130. In some embodiments, lower portions 122L (e.g., connected to the upper portions 122U) of the conductive bumps 122 and second portions 114 (e.g., connected to the first portions 112) of the conductive elements 110 may remain in physical contact with and laterally encapsulated by the insulating encapsulation 130. The insulating encapsulation 130 having a third thickness T3-1 covers the sidewalls of the second portions 114 of the conductive elements 110 and the sidewalls of the lower portions 122L of the conductive bumps 122.

The second step of thinning process may be a selective etching process or other applicable process. For example, the wet etching is highly selective of insulating material (e.g., molding compound) as compared to metal (e.g., copper or copper alloy). Slight or no appreciable amount of conductive bumps 122 or conductive elements 110 is removed after the second step of thinning process. For example, a suitable chemical solution may be applied to the thinned insulating material IM2. The second thickness T2 of the thinned insulating material IM2 is reduced to a desired third thickness (e.g., T3-1 and T3-2) without damage (or with minimal removal) to the conductive bumps 122 and the conductive elements 110. In some embodiments, before the selective etching process, a mask (not shown) is formed on the conductive bumps 122 and the conductive elements 110 for protection. And, the mask is removed after the selective etching.

A selective etching process may be performed with any suitable chemical solutions capable of etching the thinned insulating material IM2. For example, chemical solutions for etching the thinned insulating material IM2 include nitric acid, sulfuric acid, a mixed acid, or the like. The etch rate can be controlled by adjusting a concentration of the employed chemical solutions. For example, the concentration may be increased if the etch rate is too low to give reasonable efficiency. The concentration may be selected based on a thickness of the thinned insulating material IM2 needed to be removed. During the second step of thinning process, the chemical solutions for etching may have a raised temperature to accelerate the chemical reaction. Before proceeding to the next process, a cleaning process may be performed onto the first surface 130S1 of the insulating encapsulation 130.

In alternative embodiments, the insulating encapsulation 130 may be formed through one step of thinning. For example, after forming the insulating material IM1, an etching process is performed to remove the insulating material IM1 until the first portions 112 of the conductive elements 110 and the upper portions 122U of the conductive bumps 122 are exposed.

Referring to FIG. 1F and FIG. 2, a front-side buffer layer 140 is formed over the first surface 130S1 of the insulating encapsulation 130 to cover the first portions 112 of the conductive elements 110 and the upper portions 122U of the conductive bumps 122. The front-side buffer layer 140 may encapsulate the sidewalls of the first portions 112 of the conductive elements 110 and the sidewalls of the upper portions 122U of the conductive bumps 122. The front-side buffer layer 140 exposes at least a surface (e.g., surface 110a) of the conductive elements 110 and at least a surface (e.g., surface 122a) of the conductive bumps 122 for further electrical connection. The front-side buffer layer 140 may be a dielectric layer or any suitable electrically insulating layer. In some embodiments, the front-side buffer layer 140 and the insulating encapsulation 130 are of different materials. The Young's modulus (e.g., a measurement of hardness) of the insulating encapsulation 130 may be greater than the Young's modulus of the front-side buffer layer 140. A material of the front-side buffer layer 140 includes a polymer, such as polyimide (PI), polybenzoxazole (PBO), benzocyclobutene (BCB), Ajinomoto Build-up Film (ABF), or other suitable material.

The front-side buffer layer 140 may be formed through a spin-coating process, a spray coating process, a deposition process, a combination thereof, or other applicable process. In some embodiments, a planarization process is performed to provide the front-side buffer layer 140 with the substantially planar surface 140a, thereby facilitating subsequent processes. The planarization process may be a grinding process, a CMP process, a dry polishing process, a combination thereof, or other suitable process. During a planarization process, portions of the upper portions 122U of the conductive bumps 122 and/or first portions 112 of the conductive elements 110 may be further reduced. In some embodiments, the surface 140a of the front-side buffer layer 140 is substantially coplanar with the first surfaces 110a of the conductive elements 110 and the first surfaces 122a of the conductive bumps 122.

The front-side buffer layer 140 may have a uniform thickness. In alternative embodiments, the thickness T4 of the front-side buffer layer 140 may not be uniform depending on the underlying insulating encapsulation 130; however, the surface 140a of the front-side buffer layer 140 may remain planar. In some embodiments, a ratio of the thickness T4 of the front-side buffer layer 140 laterally covering the upper portions 122U of the conductive bumps 122 and the thickness T3-2 of the insulating encapsulation 130 laterally covering the lower portions 122L of the conductive bumps 122 may be substantially equal to 1.

Referring to FIG. 1G, a redistribution structure 150 is formed over the surface 140a of the front-side buffer layer 140, the first surfaces 110a of the conductive elements 110, and the first surfaces 122a of the conductive bumps 122. The semiconductor chip 120 is electrically coupled to the conductive elements 110 through the redistribution structure 150. The redistribution structure 150 includes at least one patterned dielectric layer 151 and at least one patterned conductive layer 152 alternatingly formed. After forming the redistribution structure 150, the front-side buffer layer 140 is interposed between the patterned dielectric layer 151 of the redistribution structure 150 and the insulating encapsulation 130. The front-side buffer layer 140 may be in direct contact with the patterned dielectric layer 151 and the insulating encapsulation 130. A first patterned conductive layer 152 of the redistribution structure 150 is physically and electrically connected to the conductive elements 110 and the conductive bumps 122 exposed by the front-side buffer layer 140.

The patterned dielectric layer 151 may be made of inorganic or organic semiconductor dielectric materials such as PBO, PI, BCB, or other suitable electrically insulating materials. The patterned dielectric layer 151 may be formed using a coating process, a deposition process, or other suitable process. In some embodiments, the patterned dielectric layer 151 and the front-side buffer layer 140 are of different materials. The Young's modulus of the patterned dielectric layer 151 of the redistribution structure may be greater than or substantially equal to the Young's modulus of the front-side buffer layer 140. The front-side buffer layer 140 disposed between the redistribution structure 150 and the insulating encapsulation 130 may be used as a stress buffer when forming the redistribution structure 150.

The patterned dielectric layer 151 includes a plurality of openings exposing portions of the conductive vias 140 and portions of the conductive bumps 122. Subsequently, the patterned conductive layer 152 may be formed in and over the patterned dielectric layer 151. The patterned conductive layer 152 includes conductive features such as conductive traces, contact pads, and/or contact vias. A material of the patterned conductive layer 152 includes copper, aluminum, metal alloy, or combinations thereof. In alternative embodiments, the patterned conductive layer 152 is formed prior to the patterned dielectric layer 151. The process may be performed multiple times to form a multi-layered redistribution structure as required by the circuit design.

After forming the redistribution structure 150, conductive terminals 160 may be formed on the redistribution structure 150 opposite to the conductive elements 110 for further electrical connection. The conductive terminals 160 may be electrically coupled to the semiconductor chip 120 at least through the redistribution structure 150. The top patterned dielectric layer 151T may have openings exposing at least a portion of the top patterned conductive layer 152 (e.g., under-ball metallurgy (UBM) pads). A material of the top patterned dielectric layer 151T may be different from the underlying patterned dielectric layers. The top patterned dielectric layer 151T may include solder sensitive material for protecting the patterned conductive layer 152 during a ball mounting process. The conductive terminals 160 are formed in the openings of the top patterned dielectric layer 151T to physically connect the underlying top patterned conductive layer 152. The conductive terminals 160 may include conductive balls, conductive pillars, conductive bumps, a combination thereof, or other forms and shapes formed by a ball mounting process, an electroless plating process, or other suitable process. A soldering process and a reflowing process are optionally performed for enhancement of the adhesion between the conductive terminals 160 and the redistribution structure 150.

Referring to FIG. 1H, after forming the conductive terminals 160, the temporary carrier 50 is removed to expose the semiconductor chip 120, the conductive elements 110, and the insulating encapsulation 130. After removing the temporary carrier 50, the second side 120b of the semiconductor chip 120 is substantially coplanar with the second surfaces 110b of the conductive elements 110, and a second surface 130S2 (e.g., opposite to the first surface 130S1) of the insulating encapsulation 130. A singulation process may be performed to form a plurality of semiconductor package 10. The semiconductor package 10 may be an integrated fan-out package (InFO) package.

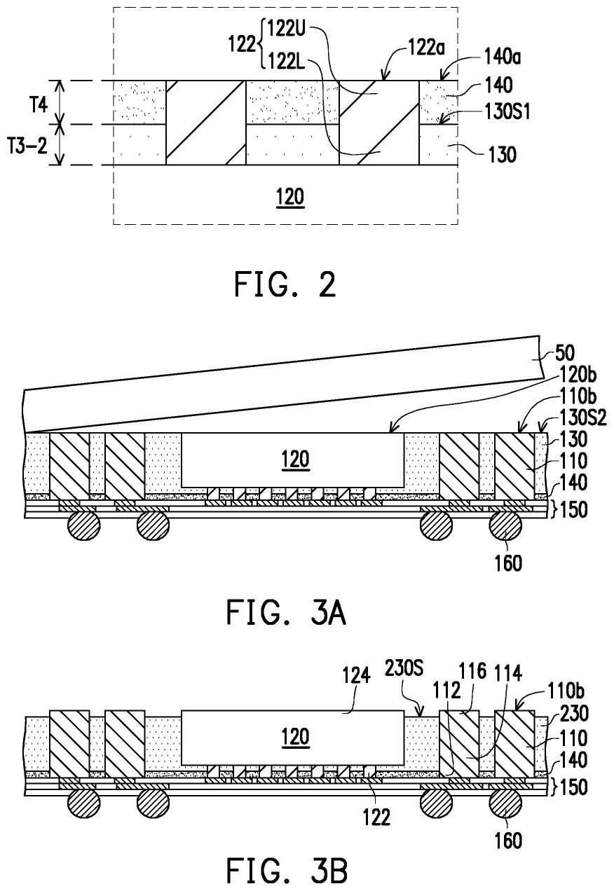

FIG. 3A to FIG. 3C are schematic cross-sectional views illustrating a manufacturing method of a semiconductor package according to an embodiment of the disclosure. The manufacturing method of the present embodiment is similar to the embodiment illustrated in FIG. 1A to FIG. 1H, the identical or similar numbers refer to the identical or similar elements throughout the drawings, and detail thereof is not repeated for brevity. Referring to FIG. 3A, after the conductive terminals 160 are formed as shown in FIG. 1G, the structure may be flipped upside down for subsequent processes. The temporary carrier 50 is removed to expose the second surface 130S2 of the insulating encapsulation 130, the second side 120b of the semiconductor chip 120, and the second surfaces 110b of the conductive elements 110. The conductive terminals 160 may or may not be present during the removal process of the temporary carrier 50. For example, after forming the redistribution structure 150, the structure (e.g., the structure shown in FIG. 1G without the conductive terminals 160) may be overturned and the temporary carrier 50 is removed before performing the subsequent processes. In such embodiments, the conductive terminals 160 may be formed after formation of back-side buffer layer (e.g., buffer layer 240 shown in FIG. 3C)

Referring to FIG. 3B, the thickness of the insulating encapsulation 130 is reduced to form an intermediate encapsulation 230. A portion of the insulating encapsulation 130 is removed to expose third portions 116 (e.g., connected to the second portions 114 and opposite to the first portions 112) of the conductive elements 110 and a rear portion 124 (e.g., opposite to the conductive bumps 122) of the semiconductor chip 120. The third portions 116 of the conductive elements 110 may be protruded from a surface 230S of the intermediate encapsulation 230. The thinning process of the insulating encapsulation 130 may be similar with the thinning process of the thinned insulating material IM2 as described in FIG. 1E. The insulating encapsulation 130 may be thinned through a selective etching process or other applicable process. A suitable chemical solution may be applied to the insulating encapsulation 130 to reduce a desired thickness of the insulating encapsulation 130 without damage (or with minimal removal) to the rear portion 124 of the semiconductor chip 120 and the conductive elements 110. Since the rear portion 124 of the semiconductor chip 120 and the conductive elements 110 are of different materials, a mask may be formed over the semiconductor chip 120 and the conductive elements 110 in turns for protection during etching, and the mask is removed after etching is complete.

Referring to FIG. 3C, a back-side buffer layer 240 is formed over the surface 230S of the intermediate encapsulation 230 to cover the third portions 116 of the conductive elements 110 and the rear portion 124 of the semiconductor chip 120. In some embodiments, the back-side buffer layer 240 covers the sidewalls of the third portions 116 of the conductive elements 110 and the sidewalls of the rear portion 124 of the semiconductor chip 120. The back-side buffer layer 240 includes a thickness that allows the back-side buffer layer 240 to act as a buffer for reducing stress. A thickness of the back-side buffer layer 240 may be similar to or different from that of the front-side buffer layer 140.

In some embodiments, the back-side buffer layer 240 exposes at least part of the third portions 116 of the conductive elements 110 for further electrical connection. The back-side buffer layer 240 may be substantially planar. In some embodiments, a surface 240a of the back-side buffer layer 240 is coplanar with the second surfaces 110b of the conductive elements 110 and the rear surface 124a of the semiconductor chip 120. In alternative embodiments, the back-side buffer layer 240 covers the second surfaces 110b of the conductive elements 110 and the rear surface 124a of the semiconductor chip 120 to act as the protective insulator for protecting the semiconductor chip 120 and the conductive elements 110 from being damaged. A material and a forming process of the back-side buffer layer 240 may be same as or similar with that of the front-side buffer layer 140. The intermediate encapsulation 230 may be harder than both of the front-side buffer layer 140 and the back-side buffer layer 240. In some embodiments, the Young's modulus of the intermediate encapsulation 230 may be greater than the Young's modulus of the front-side buffer layer 140 and the Young's modulus of the back-side buffer layer 240.

After forming the back-side buffer layer 240, a singulation process may be performed to form a plurality of semiconductor package 20. As shown in FIG. 3C, the semiconductor chip 120 and the conductive elements 110 are encapsulated by a sandwich-type of encapsulation structure comprising of the front-side buffer layer 140, the intermediate encapsulation 230, and the back-side buffer layer 240. The intermediate encapsulation 230 disposed between the front-side buffer layer 140 and the back-side buffer layer 240 has the greatest Young's modulus among the sandwich-type encapsulation structure, thereby providing the mechanical support of the semiconductor package 20. The front-side buffer layer 140 laterally covering the first portions 112 of the conductive elements 110 and the upper portions 122U of the conductive bumps 122 may be used to buffer the stress generated from subsequently formed redistribution structure 150 and the conductive terminals 160. Similarly, the back-side buffer layer 240 at least laterally covering the third portions 116 of the conductive elements 110 and the rear portion 124 of the semiconductor chip 120 may also act as a buffer for lessening stress caused by subsequently formed structures/devices thereon.

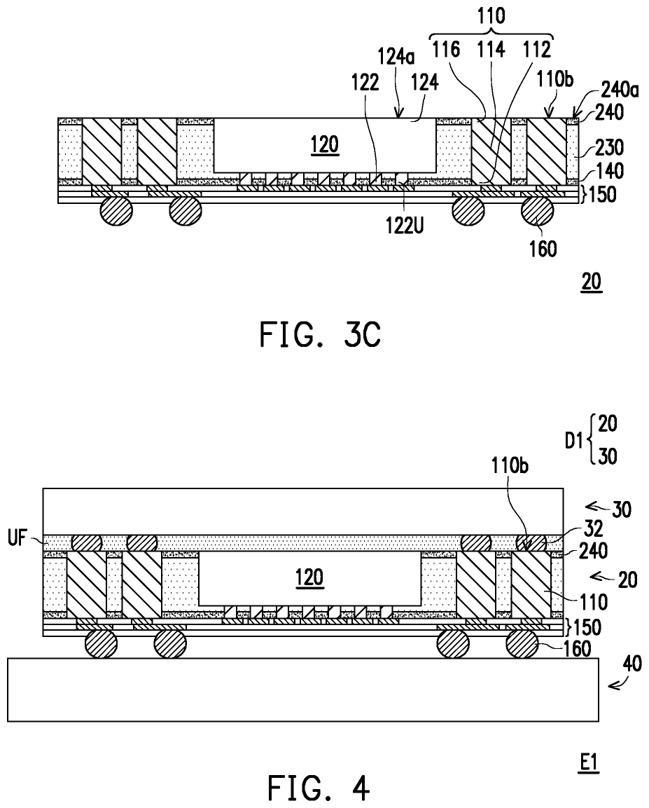

FIG. 4 is a schematic cross-sectional view illustrating an application of semiconductor package according to an embodiment of the disclosure. Referring to FIG. 4, in some embodiments, a semiconductor device 30 is disposed on the back-side buffer layer 240 of the semiconductor package 20 to form an integrated semiconductor package D1. For example, the back-side buffer layer 240 exposes at least a portion of the conductive elements 110. The semiconductor device 30 is placed on the back-side buffer layer 240, where external connectors 32 of the semiconductor device 30 are in contact with the second surfaces 110b of the conductive elements 110 to electrically connect the conductive elements 110. An underfill UF is optionally formed in the gap between the semiconductor device 30 and the semiconductor package 20 to stiffen the integrated semiconductor package D1 and protect the external connectors 32 from flexural damage.

The semiconductor device 30 may be electrically coupled to the semiconductor chip 120 through the conductive elements 110 and the redistribution structure 150. In alternative embodiments, a back-side redistribution structure (not shown) may be formed over the back-side buffer layer 240, and the semiconductor device 30 may be disposed on and electrically connected to the back-side redistribution structure. The semiconductor device 30 may be an IC package, a memory device, or other suitable semiconductor devices. Since the semiconductor device 30 is stacked over and is electrically connected to the semiconductor package 20, the integrated semiconductor package D1 having multiple packages stacked upon one another to provide additional functionality may be referred to as a package-on-package (POP) structure.

In some embodiments, the integrated semiconductor package D1 is disposed on a circuit substrate 40 to form an electronic device E1. The circuit substrate 40 may be a package substrate having integrated circuit (IC) therein, a printed circuit board (PCB), or other suitable electronic components. The conductive terminals 160 of the semiconductor package 20 may be utilized to establish electrical connections between the semiconductor package 20 and the circuit substrate 40, thereby providing the electronic device E1 of high quality and reliability. For example, the integrated semiconductor package D1 is placed on the circuit substrate 40, where the conductive terminals 160 of the semiconductor package 20 are in direct contact with the circuit substrate 40 so that the integrated semiconductor package D1 and the circuit substrate 40 are electrically connected. In other embodiments, the semiconductor package 10 as shown in FIG. 1H is connected to the circuit substrate 40 to form an electronic device. The application of the semiconductor package is not limited in the disclosure.

Based on the above, the semiconductor package includes the front-side buffer layer formed between the insulating encapsulation and the redistribution structure, so that the front-side buffer layer can be used to buffer the stress generated from a subsequently formed structures. Accordingly, the reliability and quality of the semiconductor package are improved. In addition, the total thickness of the buffer layers and the insulating encapsulation is substantially equal to the height of the conductive element or the height of the semiconductor chip, so that the entire thickness of the semiconductor package is not compromised. Moreover, the buffer layers may be formed at two opposite sides of the insulating encapsulation to form a sandwich-type of encapsulation structure for stress buffering. Furthermore, multiple semiconductor packages may be stacked upon one another to provide additional functionality to form a POP structure so as to open the possibility to various package designs.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A semiconductor package, comprising:
a semiconductor chip;
a conductive element disposed adjacent to the semiconductor chip;
an insulating encapsulation encapsulating a portion of the semiconductor chip and the conductive element;
a redistribution structure disposed on the semiconductor chip and the conductive element, wherein the semiconductor chip and the conductive element are electrically coupled to the redistribution structure; and
a first buffer layer, disposed between the redistribution structure and the insulating encapsulation and encapsulating another portion of the semiconductor chip and the conductive element.

2. The semiconductor package according to claim 1, wherein the first buffer layer is disposed on a first surface of the insulating encapsulation, a portion of the conductive element is protruded from the first surface of the insulating encapsulation and is covered by the first buffer layer.

3. The semiconductor package according to claim 1, wherein the semiconductor chip comprises a conductive bump connected to the redistribution structure, a first portion of the conductive bump is laterally covered by the insulating encapsulation, and a second portion of the conductive bump connected to the first portion is laterally covered by the first buffer layer.

4. The semiconductor package according to claim 1, wherein a surface of the first buffer layer facing the redistribution structure is substantially coplanar with a surface of the conductive element and a surface of the semiconductor chip.

5. The semiconductor package according to claim 1, wherein a Young's modulus of the insulating encapsulation is greater than a Young's modulus of the first buffer layer.

6. The semiconductor package according to claim 1, wherein a second surface of the insulating encapsulation is substantially coplanar with a rear surface of the semiconductor chip and a surface of the conductive element opposite to the redistribution structure.

7. The semiconductor package according to claim 1, further comprising:
a second buffer layer, disposed on the insulating encapsulation opposite to the first buffer layer, and covering the conductive element and the semiconductor chip.

8. The semiconductor package according to claim 7, wherein a Young's modulus of the insulating encapsulation is greater than a Young's modulus of the second buffer layer.

9. The semiconductor package according to claim 7, wherein a portion of the conductive element is exposed by the second buffer layer, the semiconductor package further comprises:
a semiconductor device, disposed on the second buffer layer, and electrically connected to the conductive element.

10. The semiconductor package according to claim 1, further comprising:
a conductive terminal, disposed on the redistribution structure opposite to the conductive element and electrically connected to the semiconductor chip through the redistribution structure.

11. A manufacturing method of a semiconductor package, comprising:
forming an insulating encapsulation to partially cover a semiconductor chip and a conductive element, wherein a portion of the conductive element and a portion of the semiconductor chip are exposed by the insulating encapsulation;
forming a first buffer layer on the insulating encapsulation to partially cover the portion of the conductive element and the portion of the semiconductor chip; and
forming a redistribution structure on the first buffer layer, wherein the redistribution structure is electrically connected to the semiconductor chip and the conductive element.

12. The manufacturing method according to claim 11, wherein forming the insulating encapsulation comprises:
forming an insulating material to bury the semiconductor chip and the conductive element;
thinning the insulating material to form a thinned insulating material; and
removing part of the thinned insulating material to form the insulating encapsulation, wherein the portion of the conductive element and the portion of the semiconductor chip are protruded from a first surface of the insulating encapsulation.

13. The manufacturing method according to claim 11, further comprising:
planarizing the first buffer layer before forming the redistribution structure.

14. The manufacturing method according to claim 13, wherein after planarizing the first buffer layer, a surface of the first buffer layer is coplanar with a surface of the conductive element and a surface of the semiconductor chip.

15. The manufacturing method according to claim 11, wherein the semiconductor chip comprises a conductive bump,
after forming the insulating encapsulation, a lower portion of the conductive bump is laterally covered by the insulating encapsulation, and
after forming the first buffer layer, an upper portion of the conductive bump connected to the lower portion is laterally covered by the first buffer layer.

16. The manufacturing method according to claim 11, further comprising:
forming an insulating material on a temporary carrier to bury the semiconductor chip and the conductive element; and
removing the temporary carrier after forming the redistribution structure so that a second surface of the insulating encapsulation is coplanar with a surface of the conductive element and a surface of the semiconductor chip.

17. The manufacturing method according to claim 11, further comprising:
removing part of the insulating encapsulation opposite to the redistribution structure to form an intermediate encapsulation after forming the redistribution structure.

18. The manufacturing method according to claim 11, further comprising:
forming a second buffer layer on the insulating encapsulation to cover the semiconductor chip and the conductive element.

19. The manufacturing method according to claim 18, wherein at least a portion of the conductive element is exposed by the second buffer layer, and the method further comprises:
disposing a semiconductor device on the second buffer layer to electrically connect the conductive element.

20. The manufacturing method according to claim 11, further comprising:
forming a conductive terminal on the redistribution structure opposite to the conductive element.
